(19) United States
(12) Patent Application Publication
(10) Pub. No.: US 2020/0373466 A1
(43) Pub. Date: Nov. 26, 2020

(54) LIGHT SOURCE DEVICE AND DISPLAY USING THE SAME

(71) Applicant: ADVANCED OPTOELECTRONIC TECHNOLOGY, INC., Hsinchu Hsien 303 (TW)

(72) Inventors: HSIN-CHIANG LIN, Hukou (TW); HOU-TE LIN, Hsinchu (TW); CHAO-HSIUNG CHANG, Hukou (TW); LUNG-HSIN CHEN, Hukou (TW); PIN-CHUAN CHEN, Hsinchu (TW); WEN-LIANG TSENG, Hsinchu (TW)

(21) Appl. No.: 16/568,906

(22) Filed: Sep. 12, 2019

(30) Foreign Application Priority Data
May 21, 2019 (CN) 201910426016.1

(51) Int. Cl. H01L 33/50; H01L 33/62; H01L 33/38; F21V 8/00

(52) U.S. Cl. CPC H01L 33/502; H01L 33/62; G02B 6/0051; G02B 6/0073; H01L 33/38

(57) ABSTRACT

A light source device for a display includes light emitting diode packages. Each light emitting diode package includes a substrate, a first light emitting diode chip emitting a first beam of light, a second light emitting diode chip emitting a second beam of light, and a package layer including a wavelength converting material. Frequency bands of the first and second light beams both have a full width at half maximum of 30 nm to 40 nm. The wavelength converting material is excited by the first and second beams to generate a third beam of light, the frequency band of the third beam of light having a full width at half maximum of 10 nm to 50 nm. A display using the light source device is also disclosed.

### FIELD

The subject matter herein generally relates to a light source device and a display with the light source device.

### BACKGROUND

Displays are widely used. A display generally includes a light source device. A quality of the light source device affects a display quality of the display.

### BRIEF DESCRIPTION OF THE DRAWINGS

Implementations of the present technology will now be described, by way of embodiment, with reference to the attached figures.

FIG. 1 is a cross-sectional view of an embodiment of a light source device.

FIG. 2 is a diagrammatic view of an embodiment of a carrier.

FIG. 3 is a diagrammatic view of another embodiment of a carrier.

FIG. 4 is a top view of part of a light source device in one embodiment.

FIG. 5 is a cross-sectional view of an embodiment of a light emitting diode package.

FIG. 6 is a spectrum diagram of a first beam of light, a second beam of light, and a third beam of light emitted by the light source device of FIG. 1.

FIG. 7 is a schematic diagram of an embodiment of the light source device of FIG. 1.

FIG. 8 is a schematic diagram of another embodiment of a light source device.

FIG. 9 is a schematic diagram of another embodiment of a light source device.

FIG. 10 is a top view of one embodiment of a light source device.

FIG. 11 is a top view of another embodiment of a light source device.

FIG. 12 is a diagrammatic view of an embodiment of a display.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

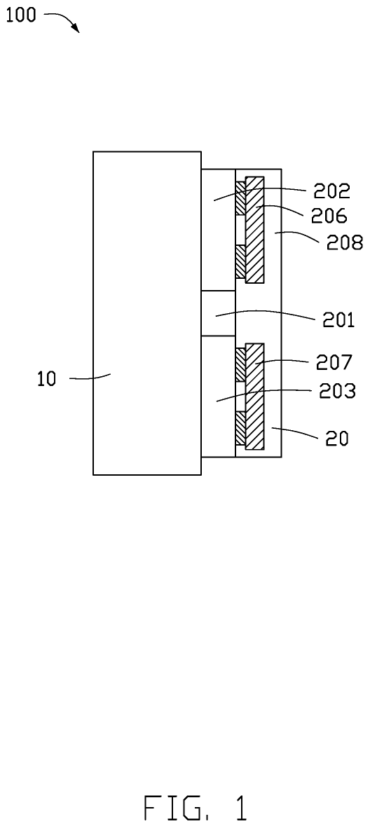

FIG. 1 illustrates an embodiment of a light source device (light source device 100). The light source device 100 includes a carrier 10 and at least one light emitting diode package 20.

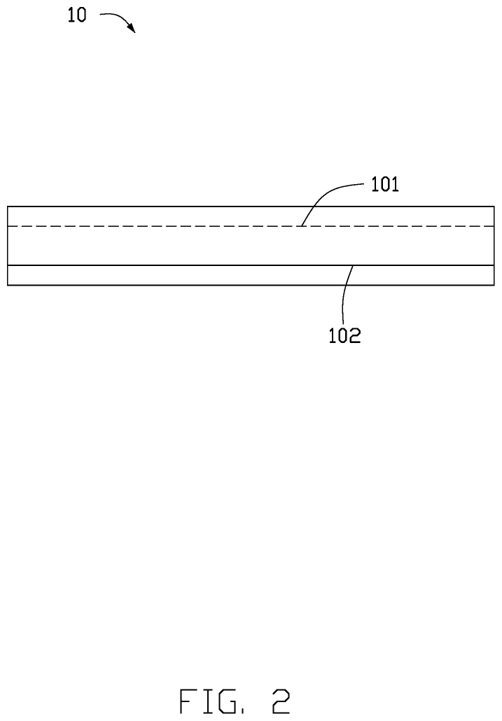

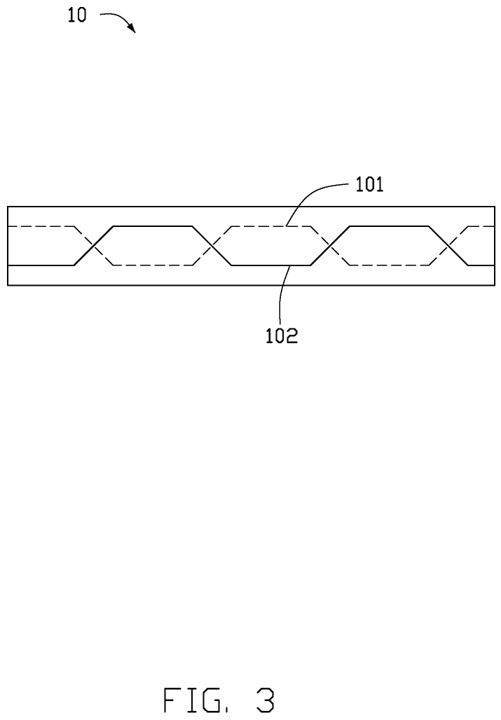

Referring to FIGS. 2 and 3, the carrier 10 includes a first control wiring 101 and a second control wiring 102. The first control wiring 101 and the second control wiring 102 are independent. In at least one embodiment, referring to FIG. 2, the first control wiring 101 and the second control wiring 102 are in parallel. In another embodiment, the first control wiring 101 and the second control wiring 102 are arranged in a cross arrangement. Specifically, the first control wiring 101 and the second control wiring 102 are substantially wave-shaped, a peak of the first control wiring 101 corresponds to a valley of the second control wiring 102, and a valley of the first control wiring 101 corresponds to a peak of the second control circuit 102. The first control wiring 101 includes a first anode wiring (not shown) and a first cathode wiring (not shown). The second control wiring 102 includes a second anode wiring (not shown) and a second cathode wiring (not shown).

Each light emitting diode package 20 includes a substrate 201, a first light emitting diode chip 206, a second light emitting diode chip 207, and a package layer 208.

The substrate 201 is formed on the carrier 10, and electrically connected to the first control wiring 101 and the second control wiring 102.

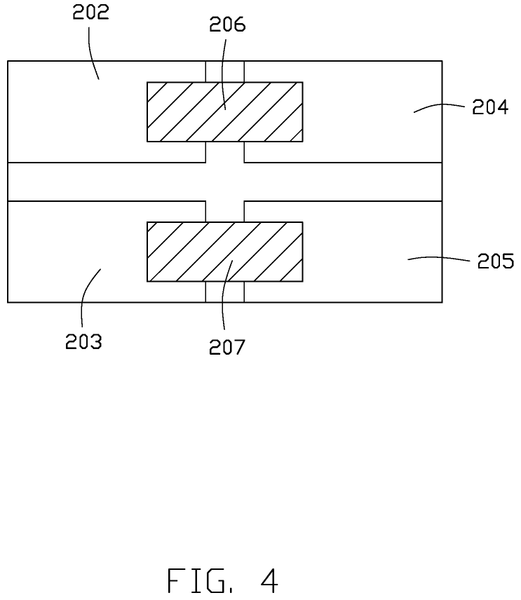

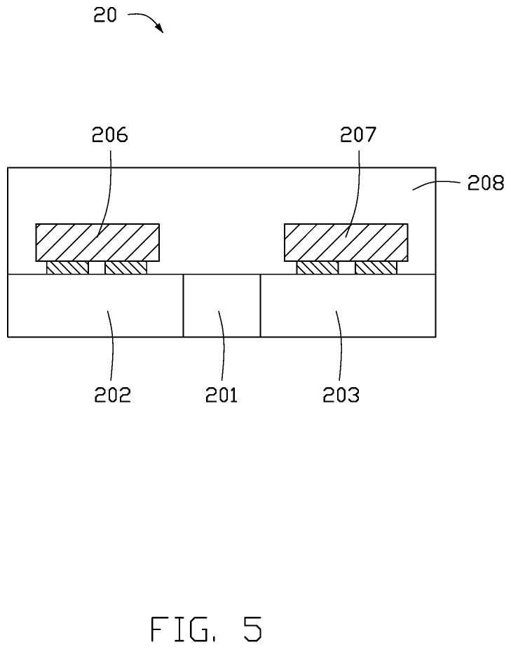

Referring to FIGS. 4 and 5, in at least one embodiment, each light emitting diode package 20 further includes a first electrode 202, a second electrode 203, a third electrode 204, and a fourth electrode 205. The first electrode 202, the second electrode 203, the third electrode 204, and the fourth electrode 205 are spaced to be separate on the substrate 201. In at least one embodiment, the first electrode 202 and the third electrode 204 are electrically connected to the first control wiring 101. The second electrode 203 and the fourth electrode 205 are electrically connected to the second control wiring 102. The first electrode 202 and the third electrode 204 are electrically connected through the first anode wiring and the first cathode wiring. The second electrode 203 and the fourth electrode 205 are electrically connected through the second anode wiring and the second cathode wiring.

In at least one embodiment, the first electrode 202, the second electrode 203, the third electrode 204, and the fourth electrode 205 may be made of a material selected from a group consisting of germanium (Ge), nickel (Ni), chromium (Cr), titanium (Ti), gold (Au), wolfram (W) and any combination thereof.

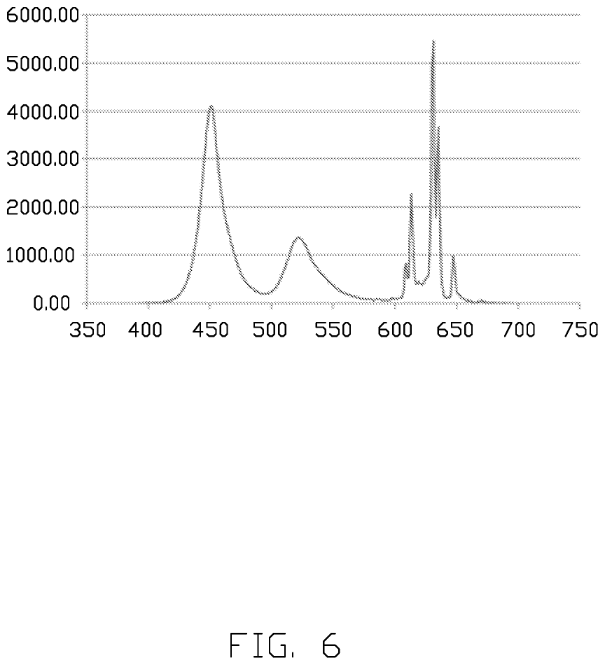

Referring to FIG. 6, the first light emitting diode chip 206 corresponds to the first control wiring 101. When the light source device 100 includes a plurality of light emitting diode packages 20, the first light emitting diode chips 206 are arranged along the first control wiring 101. The first light emitting diode chip 206 is formed on the first electrode 202 and the third electrode 204, and electrically connected to the first electrode 202 and the third electrode 204.

In at least one embodiment, the first light emitting diode chip 206 may emit a first beam of light having a wavelength of 400 nm to 480 nm. The wavelength at a peak of the first beam of light is 450 nm. A frequency band of the first beam of light has a full width at half maximum of 30 nm to 40 nm. In at least one embodiment, the first beam of light is within a narrow frequency band. The first control wiring 101 controls the first light emitting diode chip 206 to emit the first beam of light.

The second light emitting diode chip 207 corresponds to the second control wiring 102. When the light source device 100 includes a plurality of light emitting diode packages 20, the second light emitting diode chips 207 are arranged along the second control wiring 102. The second light emitting diode chip 207 is formed on the second electrode 203 and the fourth electrode 205, and electrically connected to the second electrode 203 and the fourth electrode 205.

In at least one embodiment, the second light emitting diode chip 207 may emit a second beam of light having a wavelength of 500 nm to 545 nm. The wavelength at a peak of the second beam of light is 530 nm. A frequency band of the second beam of light has a full width at half maximum of 30 nm to 40 nm. In at least one embodiment, the second beam of light is within a narrow frequency band. The second control wiring 102 controls the second light emitting diode chip 207 to emit the second beam of light.

The package layer 208 is formed on the substrate 201 and covers the first light emitting diode chip 206 and the second light emitting diode chip 207. The package layer 208 includes a material for converting wavelengths, the converted wavelengths having a narrow range. The wavelength converting material is excited by the first and second beams of light to generate a third beam of light. The third beam has a wavelength of 635 nm to 640 nm. A frequency band of the third beam of light has a full width at half maximum of 10 nm to 50 nm. In at least one embodiment, the third beam of light is within a narrow frequency band. The frequency band of the third beam of light has a full width at half maximum of about 10 nm. When the full width at half maximum of the third beam of light is reduced from 50 nm to 10 nm, a color contrast of the light source device 100 is significantly improved, thereby improving a quality of the light source device 100.

In at least one embodiment, the wavelength converting material includes a compound containing at least one tetravalent manganese ion or a nitride. In at least one embodiment, the compound containing at least one tetravalent manganese ion may have a chemical structural formula of K₂Si₂F₆:Mn⁴⁺. The nitride may have a chemical structural formula of SrLiAl₃N₄:Eu²⁺. The color contrast of the light source device 100 can be improved by controlling the full width at half maximum of the narrow frequency bands of the first and second beams of light to be within 40 nm, and the full width at half maximum of the narrow frequency band of the third beam of light to be within 50 nm. The color contrast enhances the consumer experience.

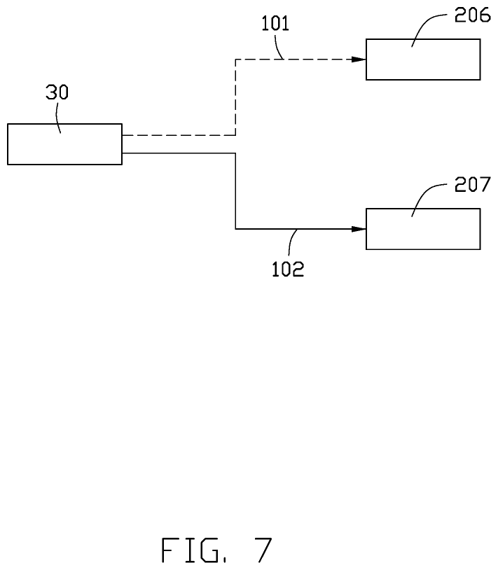

Referring to FIG. 7, the light source device 100 further includes a power source 30 electrically connected to the first control wiring 101 and the second control wiring 102. The power source 30 transmits power to the first light emitting diode chip 206 through the first control wiring 101, thereby driving the first light emitting diode chip 206 to emit the first beam of light. The power source 30 also transmits power to the second light emitting diode chip 207 through the second control wiring 102, thereby driving the second light emitting diode chip 207 to emit the second beam of light.

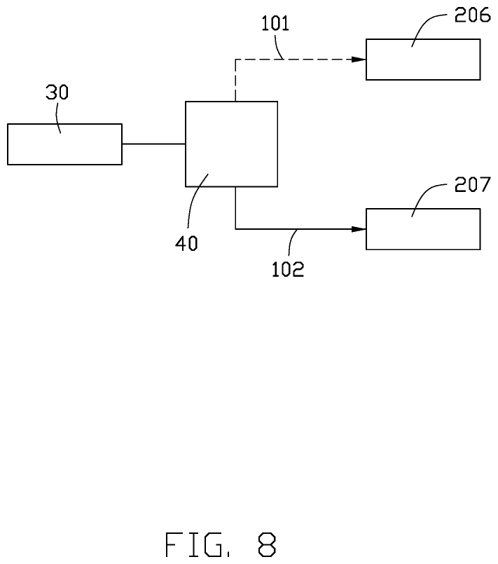

Referring to FIG. 8, in at least one embodiment, the light source device 100 further includes a first controller 40. The first controller 40 is electrically connected to the power source 30, the first light emitting diode chip 206, and the second light emitting diode chip 207. The power source 30 transmits power to the first controller 40, and the first controller 40 controls the first light emitting diode chip 206 and the second light emitting diode chip 207 to emit the first beam of light and the second beam of light, respectively.

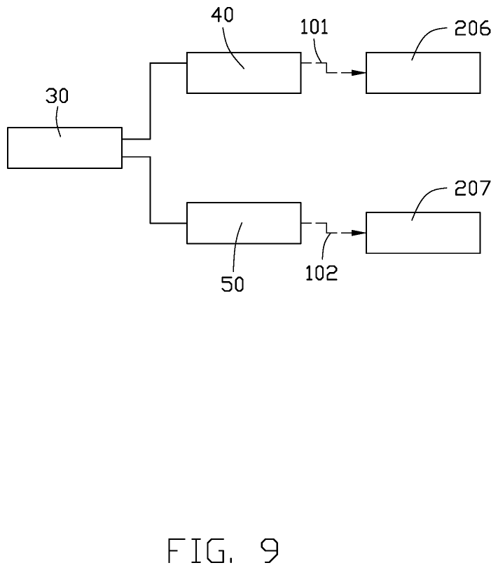

Referring to FIG. 9, in at least one embodiment, the light source device 100 further includes a second controller 50. The first controller 40 is electrically connected to the power source 30 and the first light emitting diode chip 206. The second controller 50 is electrically connected to the power source 30 and the second light emitting diode chip 207. The first controller 40 controls the first light emitting diode chip 206 to emit the first beam of light. The second controller 50 controls the second light emitting diode chip 207 to emit the second beam of light.

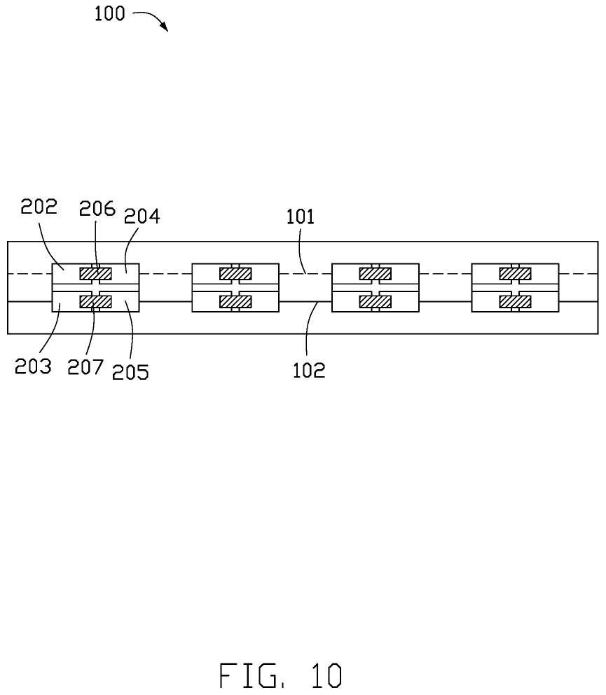

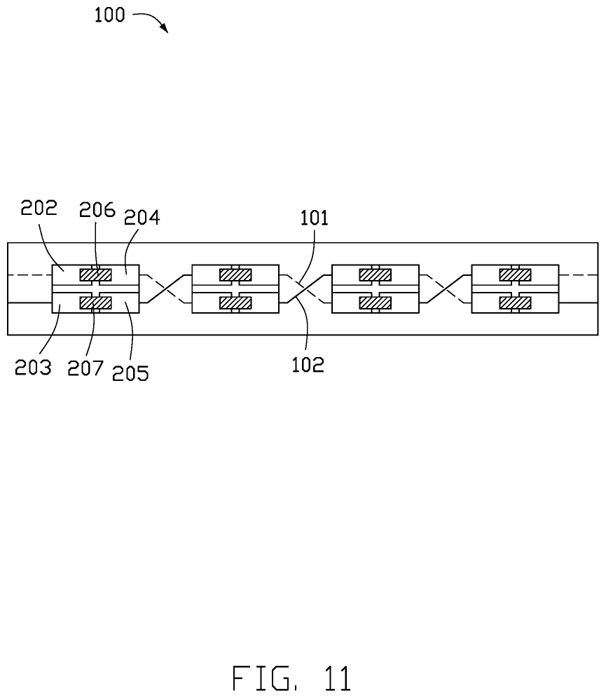

Referring to FIGS. 10 and 11, in at least one embodiment, the light source device 100 includes a plurality of light emitting diode packages 20. When the first control wiring 101 and the second control wiring 102 are arranged in parallel, the first light emitting diode chips 206 are parallel to the second light emitting diode chips 207 along an extended direction of the first control wiring 101 and the second control wiring 102. When the first control wiring 101 and the second control wiring 102 are arranged in a cross arrangement, one light emitting diode chip 206 and one second light emitting diode chip 207 may be alternately arranged along the extended direction of the first control wiring 101 and the second control wiring 102. Such arrangement facilitates mixing of the first and second beams of light. As a result, quality of the third beam of light can be improved.

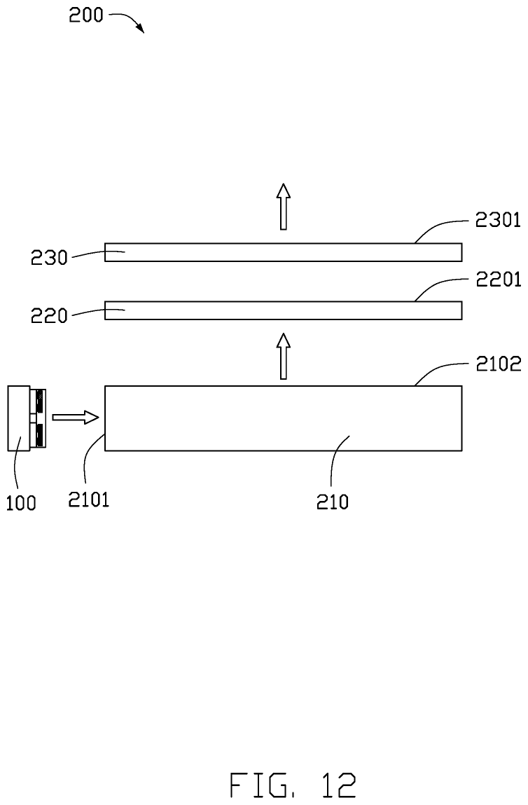

FIG. 12 illustrates an embodiment of a display 200. The display 200 includes the light source device 100, a light guide plate 210, a diffusion plate 220, and a filter 230.

The light guide plate 210 includes a light incident surface 2101. The light source device 100 faces toward the light incident surface 2101, such that the first, second, and third beams of light are incident into the light guide plate 210 from the light incident surface 2101.

The light guide plate 210 further includes a first light emitting surface 2102 connected to the light incident surface 2101. In at least one embodiment, the first light emitting surface 2102 may be perpendicular to the light incident surface 2101. The first, second, and third beams of light emitted from the first light emitting surface 2102 are incident into the diffusion plate 220.

The diffusion plate 220 is located on the first light emitting surface 2102, and includes a second light emitting surface2201 parallel to the first light emitting surface 2102. The first, second, and third beams of light emitted from the second light emitting surface2201 are incident into the filter 230.

The filter 230 is located on the second light emitting surface2201, and includes a third light emitting surface 2301. The first, second, and third beams of light are emitted from the third light emitting surface 2301.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

1. A light source device comprising:
a plurality of light emitting diode packages each comprising:
a substrate;
a first light emitting diode chip formed on the substrate to emit a first beam of light;
a second light emitting diode chip formed on the substrate to emit a second beam of light; and
a package layer formed on the substrate and covering the first light emitting diode chip and the second light emitting diode chip;
wherein a frequency band of the first beam of light has a full width at half maximum of 30 nm to 40 nm, a frequency band of the second beam of light has a full width at half maximum of 30 nm to 40 nm, the package layer comprises a wavelength converting material, the wavelength converting material is excited to generate a third beam of light by the first beam of light and the second beam of light, a frequency band of the third beam of light has a full width at half maximum of 10 nm to 50 nm; a plurality of first light emitting diode chips is arranged along an extended direction in a wave-shaped, a plurality of second light emitting diode chips is arranged along the extended direction in a wave-shaped, the plurality of first light emitting diode chips and the plurality of second light emitting diode chips are arranged in a cross arrangement, the plurality of first light emitting diode chips and the plurality of first light emitting diode chips are alternately arranged along the extended direction.

2. The light source device of the claim 1, wherein the first beam of light has a wavelength of 400 nm to 480 nm, the second beam of light has a wavelength of 500 nm to 545 nm, the third beam has a center wavelength of 635 nm to 640 nm.

3. The light source device of the claim 1, wherein the wavelength converting material comprises a compound containing at least one tetravalent manganese ion or nitride, the compound containing at least one tetravalent manganese has a chemical structural formula of K₂Si₂F₆:Mn⁴⁺, the nitride has a chemical structural formula of SrLiAl₃N₄:Eu²⁺.

4. The light source device of the claim 1, wherein the light source device further comprises a carrier comprising a first control wiring and a second control wiring, the first control wiring and the second control wiring are independent of each other, the substrate is formed on the carrier, and electrically connected to the first control wiring and the second control wiring, the first control wiring controls the first light emitting diode chip to emit the first beam of light, the second control wiring controls the second light emitting diode chip to emit the second beam of light.

5. The light source device of the claim 4, wherein the first control wiring and the second control wiring are arranged in a cross arrangement the plurality of the first light emitting diode chips is arranged along the first control wiring, the plurality of the second light emitting diode chips is arranged along the second control wiring.

6. The light source device of the claim 4, wherein each of the plurality of light emitting diode packages further comprises a first electrode, a second electrode, a third electrode, and a fourth electrode, the first electrode, the second electrode, the third electrode, and the fourth electrode are spaced formed on the substrate; the first light emitting diode chip is formed on the first electrode and the third electrode, and electrically connected to the first electrode and the third electrode; the second light emitting diode chip is formed on the second electrode and the fourth electrode, and electrically connected to the second electrode and the fourth electrode; the first electrode and the third electrode are electrically connected to the first control wiring, the second electrode and the fourth electrode are electrically connected to the second control wiring.

7. The light source device of the claim 4, wherein the light source device further comprises a power source to transmit power to the first control wiring and the second control wiring.

8. A display comprising:
a light source device comprising:
a plurality of light emitting diode packages each comprising:
a substrate;
a first light emitting diode chip formed on the substrate to emit a first beam of light;
a second light emitting diode chip formed on the substrate to emit a second beam of light; and
a package layer formed on the substrate and covering the first light emitting diode chip and the second light emitting diode chip; and
a light guide plate comprising a light incident surface;
wherein a frequency band of the first beam of light has a full width at half maximum of 30 nm to 40 nm, a frequency band of the second beam of light has a full width at half maximum of 30 nm to 40 nm, the package layer comprises a wavelength converting material, the wavelength converting material is excited to generate a third beam of light by the first beam of light and the second beam of light, a frequency band of the third beam of light has a full width at half maximum of 10 nm to 50 nm; a plurality of first light emitting diode chips is arranged along an extended direction in a wave-shaped, a plurality of second light emitting diode chips is arranged along the extended direction in a wave-shaped, the plurality of first light emitting diode chips and the plurality of second light emitting diode chips are arranged in a cross arrangement, the plurality of first light emitting diode chips and the plurality of first light emitting diode chips are alternately arranged along the extended direction; the light source device faces toward the light incident surface.

9. The display of the claim 8, wherein the first beam of light has a wavelength of 400 nm to 480 nm, the second beam of light has a wavelength of 500 nm to 545 nm, the third beam has a center wavelength of 635 nm to 640 nm.

10. The display of the claim 8, wherein wavelength converting material comprises a compound containing at least one tetravalent manganese ion or nitride, the compound containing at least one tetravalent manganese has a chemical structural formula of K₂Si₂F₆:Mn⁴⁺, the nitride has a chemical structural formula of SrLiAl₃N₄:Eu²⁺.

11. The display of the claim 8, wherein the light source device further comprises a carrier comprising a first control wiring and a second control wiring, the first control wiring and the second control wiring are independent of each other, the substrate is formed on the carrier, and electrically connected to the first control wiring and the second control wiring, the first control wiring controls the first light emitting diode chip to emit the first beam of light, the second control wiring controls the second light emitting diode chip to emit the second beam of light.

12. The display of the claim 11, wherein the first control wiring and the second control wiring are arranged in a cross arrangement the plurality of the first light emitting diode chips is arranged along the first control wiring, the plurality of the second light emitting diode chips is arranged along the second control wiring.

13. The display of the claim 11, wherein each of the plurality of light emitting diode package further comprises a first electrode, a second electrode, a third electrode, and a fourth electrode, the first electrode, the second electrode, the third electrode, and the fourth electrode are spaced formed on the substrate; the first light emitting diode chip is formed on the first electrode and the third electrode, and electrically connected to the first electrode and the third electrode; the second light emitting diode chip is formed on the second electrode and the fourth electrode, and electrically connected to the second electrode and the fourth electrode; the first electrode and the third electrode are electrically connected to the first control wiring, the second electrode and the fourth electrode are electrically connected to the second control wiring.

14. The display of the claim 11, wherein the light source device further comprises a power source to transmit power to the first control wiring and the second control wiring.

15. The display of the claim 8, wherein the light guide plate further comprises a first light emitting surface connected to the light incident surface, the display further comprises a diffusion plate located on the first light emitting surface.

16. The display of the claim 15, wherein the diffusion plate comprises a second light emitting surface parallel to the first light emitting surface, the display further comprises a filter located on the second light emitting surface.
